(19) United States
(12) Patent Application Publication
(10) Pub. No.: US 2001/0000214 A1
(43) Pub. Date: Apr. 12, 2001

(54) Oscillator which consumes less power and becomes stabile in short time

(76) Inventor: Satoshi Aragaki, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/725,889

(22) Filed: Nov. 30, 2000

(30) Foreign Application Priority Data
Mar. 12, 1999 (JP) 345310/1999

(51) Int. Cl. H03B 5/08; H03B 5/18

(52) U.S. Cl. 331/167

(57) ABSTRACT

An oscillator is composed of a feedback circuit and an amplifying circuit. The feedback circuit has first and second terminals. The feedback circuit shifts a phase of a first signal inputted to the first terminal by substantially 180° to output a second signal from the second terminal. The amplifying circuit includes an inverter and a variable resistor element. The inverter has an output terminal and an input terminal. The output terminal of the inverter is electrically connected to the first terminal. The input terminal of the inverter is electrically connected to the second terminal. The variable resistor element has first and second variable resistor terminals. A resistance between the first and second variable resistor terminals is variable. The first variable resistor terminal is electrically connected to the first terminal and the second variable resistor terminal is electrically connected to the second terminal.

### BACKGROUND OF THE INVENTION

1. 1. Field of the Invention

2. The present invention relates to an oscillator. More particular, the present invention relates to an oscillator, which consumes less electric power and also becomes stable in a short time after an oscillation of the oscillator is started.

3. 2. Description of the Related Art

4. An oscillator has been widely used for generating a clock signal of apparatuses such as a computer and so on. Such an oscillator is desired to output a clock signal as soon as possible after it is started. Moreover, the oscillator is desired to reduce its power consumption.

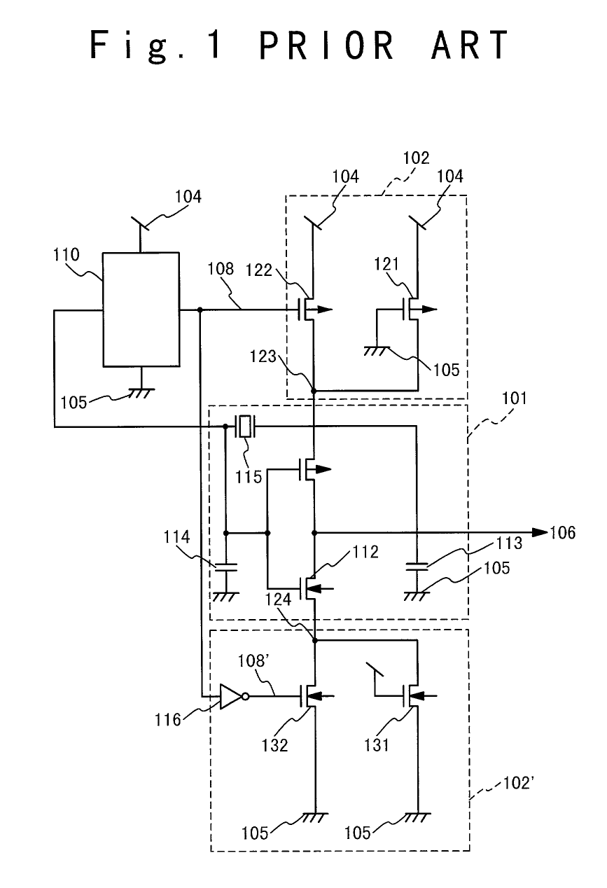

5. Such an oscillator is disclosed in Japanese Laid Open Patent Application (JP-A-Showa, 62-225006). As shown in FIG. 1, the known oscillator is provided with an oscillator 101, variable resistance controllers 102, 102′, and a delay signal generator 110.

6. The oscillator 101 is composed of a P-channel transistor 111, an N-channel transistor 112, capacitors 113, 114 and an oscillation device 115. The oscillation device 115 is made of quartz or ceramic.

7. The variable resistance controller 102 is composed of P-channel transistors 121, 122.

8. The variable resistance controller 102′ is composed of an inverter 116 and N-channel transistors 131, 132.

9. The oscillator 101 starts an oscillation when it is provided with a power. The delay signal generator 110 detects that the oscillator 101 starts the oscillation. After an elapse of a certain delay time, the delay signal generator 110 switches an output terminal 108 from a Low level to a High level. The delay time is defined such that the oscillation of the oscillator 101 becomes stable within the delay time.

10. The variable resistance controller 102 is inserted between the oscillator 101 and a power supply terminal 104. A resistance value between the power supply terminal 104 and a terminal 123 connected to the oscillator 101 is changed on the basis of a potential of the output terminal 108.

11. The variable resistance controller 102′ is inserted between the oscillator 101 and a ground terminal 105. A resistance value between the ground terminal 105 and a terminal 124 connected to the oscillator 101 is changed on the basis of the potential of the output terminal 108.

12. Immediately after the start of the oscillation in the oscillator 101, a voltage of the output terminal 108 of the delay signal generator 110 is set at the Low level. At this time, the P-channel transistors 121, 122 and the N-channel transistors 131, 132 are all turned on. After the elapse of the above-mentioned delay time, the potential of the output terminal 108 is switched to the High level. The P-channel transistor 122 and the N-channel transistor 132 are turned off. A resistance value between the power supply terminal 104 and the terminal 123 and a resistance value between the ground terminal 105 and the terminal 124 are made greater as the potential of the output terminal 108 is switched to the High level. The on-resistances of the P-channel transistor 121 and the N-channel transistor 131 are defined such that a current flowing through them to the oscillator 101 becomes a substantially minimum current under which the oscillation can be kept.

13. In this oscillator, at the time of the start of the oscillation, a large current is sent to the oscillator 101. After the oscillation becomes stable, the substantially minimum current under which the oscillation can be kept is sent to the oscillator 101. This enables the reduction in the time until the oscillation of the oscillator becomes stable, and also enables the reduction in the power consumption of the oscillator.

14. Also, another oscillator is disclosed in Japanese Laid Open Patent Application (JP-A-Showa, 62-225004). In the oscillator, the variable resistance controller 102′ is removed from the oscillator shown in FIG. 1 and a terminal 124 and a ground terminal 105 are directly connected to each other.

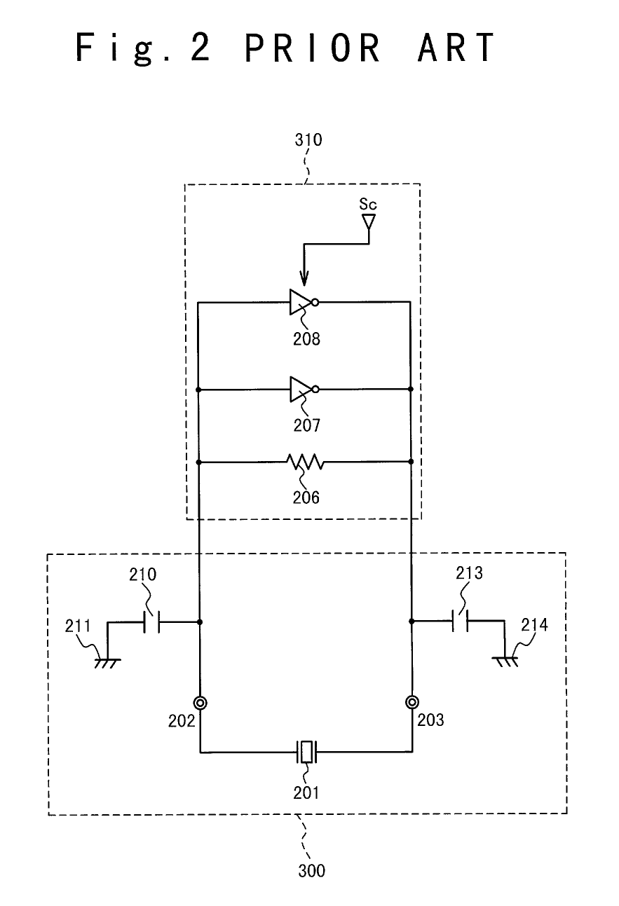

15. Moreover, still another oscillator is disclosed in Japanese Laid Open Patent Application (JP-A-Heisei, 10-98335). FIG. 2 shows the configuration of the other known oscillator. The other known oscillator is provided with an oscillator 300 and an amplifier 310.

16. The oscillator 300 has a quarts oscillating element 201 and capacitors 210, 213. One terminal of the quarts oscillating element 201 is connected to a terminal 202, and the other terminal thereof is connected to a terminal 203. The terminal 202 is connected to one terminal of the capacitor 210, and the other terminal of the capacitor 210 is connected to a ground terminal 211 having a ground potential. The terminal 203 is connected to one terminal of the capacitor 213. The other terminal of the capacitor 213 is connected to a ground terminal 214 having a ground potential.

17. The amplifier 310 is connected to the terminals 202, 203. The amplifier 310 has a feedback resistor 206, a first inverter 207 and a second inverter 208 that are connected in parallel to each other. Output terminals of the first inverter 207 and the second inverter 208 are both connected to the terminal 203. The second inverter 208 has a drive power greater than that of the first inverter 207. The second inverter 208 is enabled or disabled in accordance with an outer signal Sc.

18. The oscillator 300 and the amplifier 310 constitute a positive feedback loop. Accordingly, when a power supply begins to be sent to the oscillator, a voltage of the terminal 203 is oscillated at a natural frequency of the quarts oscillating element 201.

19. The operations of the other known oscillator will be described below. At first, a power supply voltage is sent to the first inverter 207 and the second inverter 208. At this time, the second inverter 208 is enabled in accordance with the outer signal Sc. The first inverter 207 and the second inverter 208 output the voltage at the High level or the Low level. It is indefinite whether the voltage of the High level or the Low level is outputted. It is determined in accordance with a disturbance. The voltage of any of the High level and the Low level is sent to one terminal of the quarts oscillating element 201. Accordingly, the quarts oscillating element 201 starts the oscillation at its natural frequency. This oscillation causes a voltage at the terminal 203 to be slightly oscillated. The oscillated voltage is positively fed back, and its amplitude gradually increases. Finally, the voltage at the terminal 203 is oscillated at an amplitude determined by the power supply voltage sent to the first and second inverters 207, 208 at the natural frequency of the quarts oscillating element 201.

20. When the oscillation is stable, the second inverter 208 is disabled by the outer signal Sc. In the oscillator, when the oscillation of the voltage at the terminal 203 is started, the second inverter 208 is enabled to thereby shorten a time until the oscillation of the voltage at the terminal 203 becomes stable. Also, after the oscillation has been stabilized, the second inverter 208 is disabled to thereby reduce the power consumption of the oscillator when the oscillation becomes stable.

21. The other known oscillator provides a greater suppression effect of the power consumption if an oscillation frequency is higher. This is because in a case of the high oscillation frequency, a penetration current flowing through the first and second inverters 207, 208 leads to the power consumption of the other known oscillator. Here, the penetration current of the inverter 207 or 208 implies a current which flows from a power supply terminal to a ground terminal, when the output of the inverter 6 is inverted.

22. If the oscillation frequency is low, the other known oscillator does not provide the sufficient suppression effect of the power consumption. This is because the main power consumption result from a charging and discharging current associated with the charging and discharging operations of the capacitors 210, 213. The charging and discharging current is not suppressed in the other known circuit.

23. It is desirable to provide an oscillator whose power consumption is further reduced. In particular, it is desirable to provide the oscillator whose power consumption is further reduced when the oscillation frequency is low.

### SUMMARY OF THE INVENTION

24. Therefore, an object of the present invention is to provide an oscillator whose power consumption is reduced.

25. Another object of the present invention is to provide an oscillator in which a time required to stabilize an oscillation is short.

26. Still another object of the present invention is to reduce a current for charging and discharging a capacitor contained in an oscillator.

27. Still another object of the present invention is to reduce a power consumption of an oscillator oscillated at a frequency equal to or less than 1 MHz, especially, at a frequency of 32 kHz.

28. In order to achieve an aspect of the present invention, an oscillator is composed of a feedback circuit and an amplifying circuit. The feedback circuit has first and second terminals. The feedback circuit shifts a phase of a first signal inputted to the first terminal by substantially 180° to output a second signal from the second terminal. The amplifying circuit includes an inverter and a variable resistor element. The inverter has an output terminal and an input terminal. The output terminal of the inverter is electrically connected to the first terminal. The input terminal of the inverter is electrically connected to the second terminal. The variable resistor element has first and second variable resistor terminals. A resistance between the first and second variable resistor terminals is variable. The first variable resistor terminal is electrically connected to the first terminal and the second variable resistor terminal is electrically connected to the second terminal.

29. Since the resistance of the variable resister element is variable, a current flowing through the oscillator can be adjusted as necessary. Immediately after the start of the oscillation, the resistance of the variable resister is made smaller. An amplitude of an oscillation signal outputted by the oscillator is sharply made greater. After the oscillation becomes stable, the resistance of the variable resister is made greater to thereby suppress the power consumption.

30. The variable resistor element may be composed of a resistor connected between the first and second variable resistor terminals, and a switching element connected to the resistor in parallel to each other. The first and second variable resistor terminals are substantially short-circuited by the switching element when the switching element is turned on.

31. The first variable resistor terminal may be connected to the first terminal. In this case, the second variable resistor terminal may be connected to the output terminal.

32. The first variable resistor terminal is connected to the input terminal and the second variable resistor terminal is connected to the second terminal.

33. The inverter and the variable resistor element may be connected in parallel to each other.

34. The amplifying circuit may further include a feedback resistor connected between third and fourth terminals. In this case, the inverter and the variable resistor section are serially connected between the third and fourth terminals in parallel to the feedback resistor. Also, the third terminal is electrically connected to the first terminal, and the fourth terminal is electrically connected to the second terminal.

35. The amplifying circuit may further include a feedback resistor. In this case, the feedback resistor and the variable resistor section are serially connected between third and fourth terminals. Also, the inverter is connected between the third and fourth terminals in parallel to the feedback resistor and the variable resistor section. The third terminal is electrically connected to the first terminal, and the fourth terminal is electrically connected to the second terminal.

36. The feedback circuit may include a quarts oscillating element connected between the first and second terminal, a first grounded terminal, a first capacitor connected between the first terminal and the first grounded, a second grounded terminal, and a second capacitor connected between the second terminal and the second grounded terminal.

37. A natural frequency of the quarts oscillating element is desirably selected such that a charging and discharging current for charging and discharging the first and second capacitor is larger than a penetrating current flowing through the inverter when the inverter inverts an output voltage outputted from the output terminal.

38. In order to achieve another aspect of the present invention, a method of operating the above-mentioned oscillator is composed of:

39. supplying a power supply voltage to the inverter;

40. setting the resistance to a first resistance at a timing when the supplying is started; and

41. setting the resistance to a second resistance, a predetermined period after the timing, wherein the second resistance is larger than the first resistance.

42. The predetermined period is desirably determined such that setting the resistance to the second resistance is executed after an amplitude of an oscillation occurring in the oscillator is saturated.

43. In order to achieve still another aspect of the present invention, a method of operating the above-mentioned oscillator is composed of:

44. supplying a power supply voltage to the inverter;

45. turning on the switching element at a timing when the supplying is started;

46. turning off the switching element a predetermined period after the timing.

### BRIEF DESCRIPTION OF THE DRAWINGS

47. FIG. 1 shows a configuration of a known oscillator;

48. FIG. 2 shows a configuration of another known oscillator;

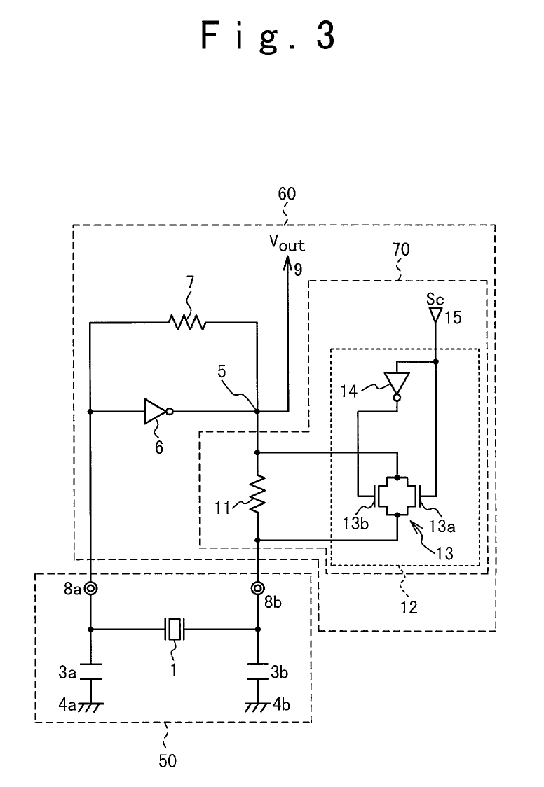

49. FIG. 3 shows a configuration of an oscillator of a first embodiment of the present invention;

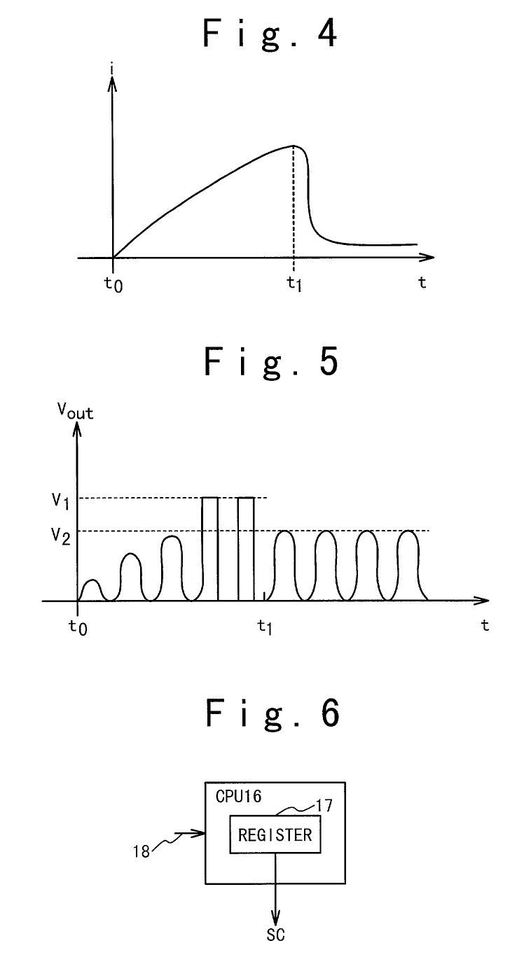

50. FIG. 4 shows a temporal change in an amplitude i of a current flowing through the oscillator of the first embodiment;

51. FIG. 5 shows a waveform of an output voltage Vout;

52. FIG. 6 shows a configuration of a circuit for generating a control signal Sc;

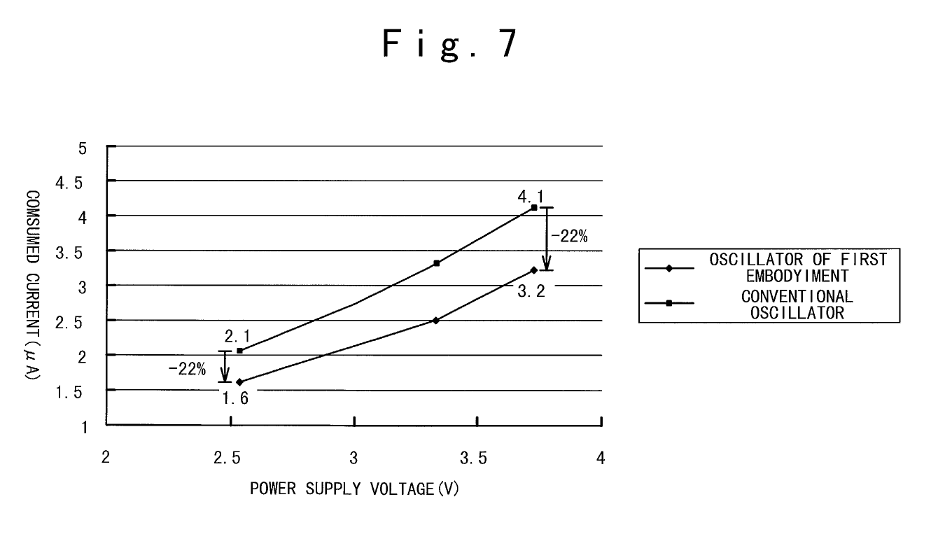

53. FIG. 7 shows a consumed current of the oscillator of the first embodiment of the present invention;

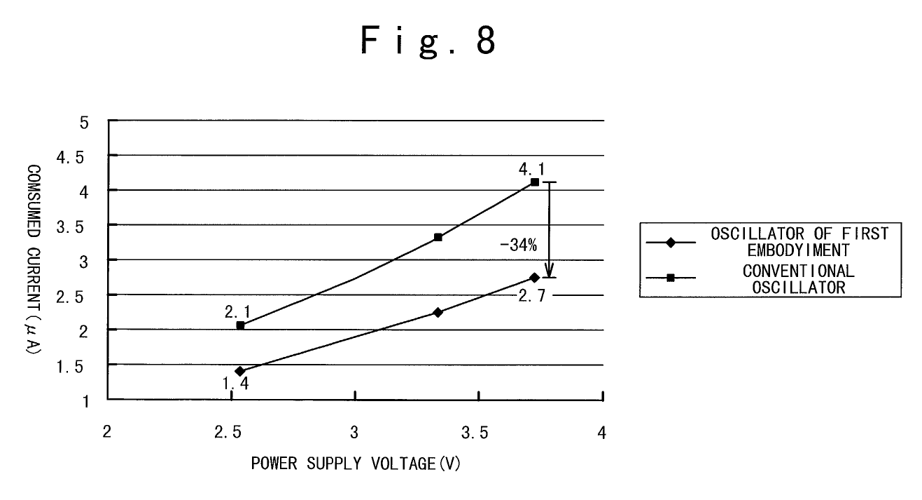

54. FIG. 8 shows a consumed current of the oscillator of the first embodiment of the present invention;

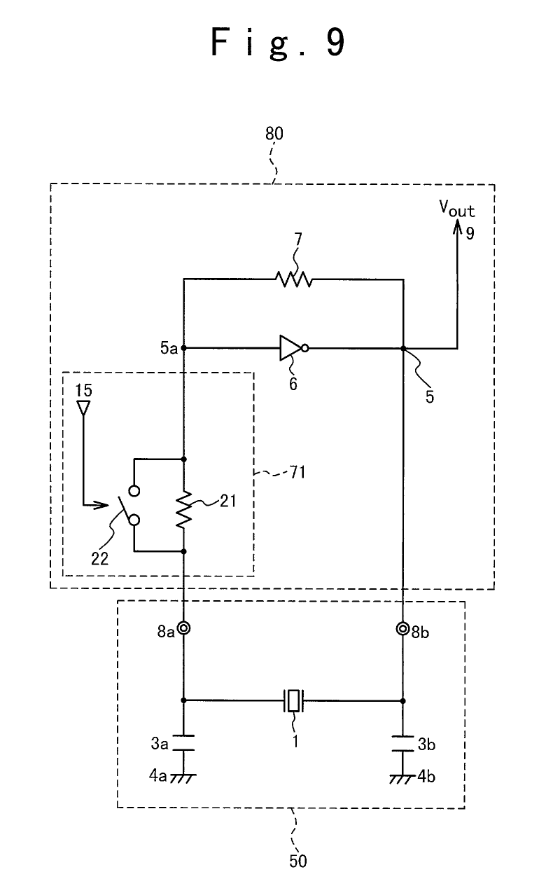

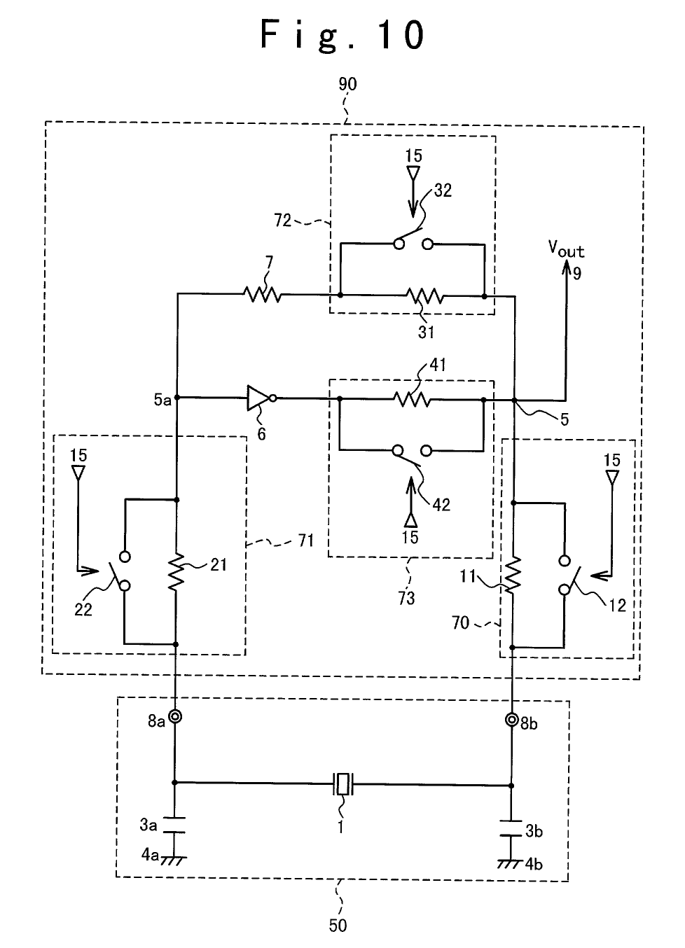

55. FIG. 9 shows a configuration of an oscillator of a second embodiment; and

56. FIG. 10 shows a configuration of an oscillator of a third embodiment.

### DESCRIPTION OF THE PREFERRED EMBODIMENTS

57. Oscillators of the present invention will be described below with reference to the attached drawings.

58. First Embodiment

59. With reference to FIG. 3, an oscillator of the first embodiment is provided with a feedback circuit 50 and an amplifying circuit 60.

60. The feedback circuit 50 includes a quarts oscillating element 1 and capacitors 3a, 3b. The feedback circuit 50 shifts a phase of a voltage inputted to a terminal 8b to outputs another voltage from a terminal 8a. The phase shifted by the feedback circuit 50 is substantially 180° at a natural frequency of the quarts oscillating element 1. One terminal of the quarts oscillating element 1 is connected to the terminal 8a, and the other terminal is connected to the terminal 8b. The terminal 8a is connected to one terminal of the capacitor 3a. The other terminal of the capacitor 3a is connected to a ground terminal 4a and grounded. The terminal 8b is connected to one terminal of the capacitor 3b. The other terminal of the capacitor 3b is connected to a ground terminal 4b. The other terminal of the capacitor 3b is grounded.

61. The amplifying circuit 60 includes an inverter 6, a feedback resistor 7 and a current adjuster 70. An input terminal of the inverter 6 and one terminal of the feedback resistor 7 are connected to the terminal 8a. The output terminal of the inverter 6 and the other terminal of the feedback resistor 7 are connected to a terminal 5. The terminal 5 is connected to an output terminal 9. An output signal Vout is outputted from the output terminal 9. The terminal 5 is further connected to the current adjuster 70. The current adjuster 70 is connected to the terminal 8b.

62. The current adjuster 70 includes a resistor 11 and a switch 12 that are connected parallel to each other. The switch 12 includes a transfer gate 13, an inverter 14 and a control signal input terminal 15. The transfer gate 13 is composed of a P-channel transistor 13a and an N-channel transistor 13b. Sources of the P-channel transistor 13a and the N-channel transistor 13b are connected to each other. Drains of the N-channel transistor 13a and the P-channel transistor 13b are connected to each other. A gate of the P-channel transistor 13a is connected to the control signal input terminal 15. A gate of the N-channel transistor 13b is connected to an output terminal of the inverter 14. The input terminal of the inverter 14 is connected to the control signal input terminal 15. A control signal Sc is inputted to the control signal input terminal 15. The switch 12 is turned on when the control signal Sc is at the Low level. At this time, the terminal 5 and the terminal 8b are short-circuited through the switch 12. Also, this switch 12 is turned off when the control signal SC is at the High level. If the switch 12 is turned off, the terminal 5 and the terminal 8 are electrically connected through the resistor 11 to each other.

63. The operations of the oscillator are described below. The feedback circuit 50 and the amplifying circuit 60 constitute a positive feedback loop. The oscillator generates the output signal Vout having the same frequency as the natural frequency of the quarts oscillating element 1. The output signal Vout is outputted from the output terminal 9 included in the amplifying circuit 60.

64. At a time of a start of the oscillation (t=t₀), a power supply voltage starts to be supplied to the inverter 6. At this time, a control signal Sc is at the Low level. The terminal 5 and the terminal 8b are short-circuited. Then, as shown in FIG. 4, an amplitude i of a current flowing through the oscillator becomes gradually greater. Similarly, as shown in FIG. 5, an amplitude of the output signal Vout becomes gradually greater.

65. After an elapse of a certain time from the start of the oscillation (t=t₀), a current outputted from the inverter 6 is saturated. At this time, a waveform of the output signal Vout is substantially rectangular. The amplitude of the output signal Vout is V₁, as shown in FIG. 5.

66. Next, when a predetermined time elapses from the start of the oscillation (t=t₁), a control signal Sc is set to the High level. The switch 12 is turned off. The current flowing through the oscillator is passed through the resistor 11. This results in that the current flowing through the oscillator is made smaller. The amplitude of the output signal Vout becomes V₂, which is smaller than V₁. After that, the oscillator oscillates in a stable state.

67. FIG. 6 shows a circuit generating the control signal Sc to be inputted to the control signal input terminal 15. The circuit includes a CPU 16. The CPU 16 includes a register 17. The register 17 outputs the control signal Sc. The CPU 16 stores therein a program that is executed when a reset signal 18 is switched from the Low level to the High level. The register 17 is controlled in accordance with the program. In accordance with the program, the register 17 maintains the control signal Sc at the Low level until the elapse of the predetermined period t₁ after the reset signal 18 is switched from the Low level to the High level. In succession, the register 17 switches the control signal Sc to the High level.

68. It is desirable that the program can be rewritten. A user can change the period t₁ while the control signal Sc is at the Low level by rewriting the program.

69. In the oscillator of the embodiment, the output terminal of the inverter 6 and the terminal 8b are short-circuited at the time of the start of the oscillation. The oscillation becomes stable in a short time. Moreover, in the oscillator of the embodiment, after the oscillation becomes stable, the output terminal of the inverter 6 and the terminal 8b are connected through the resistor 11 to each other. Thereby, the charging and discharging current of the capacitor 3b is suppressed so that the power consumption of the oscillator is reduced at the time of the stable oscillation.

70. The power consumption reducing effect is evident as the oscillation frequency of the oscillator is lower. The power consumption of the oscillator results from a current penetrating the inverter 6 and a current for charging and discharging of the capacitor 3a and 3b. The lower is the oscillation frequency, the larger part of the power consumption results from the charging and discharging current of the capacitor 3a, 3b.

71. It is preferable that the oscillator of the embodiment is used as the oscillator having the low oscillation frequency. Desirably, the oscillation frequency is low such that the charging and discharging current for charging and discharging capacitors 3a and 3b is larger than a penetrating current flowing through the inverter 6 when the inverter 6 inverts an output voltage outputted from the output terminal of the inverter 6. In other words, the natural frequency of the quarts oscillating element 1 is selected such that the charging and discharging current is larger than the penetrating current flowing through the inverter 6.

72. FIG. 7 shows the currents flowing through the oscillators in this embodiment and the above-mentioned oscillator. In both oscillators, the oscillation frequency is 32 kHz. A vertical axis of FIG. 7 shows the values of the currents flowing through the oscillators. A horizontal axis of FIG. 7 shows a power supply voltage sent to the oscillator. A resistance of the resistor 11 mounted in the oscillator in this embodiment is assumed to be 300 kΩ.

73. If the power supply voltage is 2.6 V, the current flowing through the oscillator in this embodiment is 1.6 μA, and the current flowing through the oscillator in the conventional oscillator is 2.1 μA. Also, if the power supply voltage is 3.7 V, the current flowing through the oscillator in this embodiment is 3.2 μA, and the current flowing through the oscillator in the conventional example is 4.1 μA. From this result, in the oscillator in this embodiment, a current is reduced by about 22% as compared with the oscillator in the conventional oscillator.

74. FIG. 8 is a graph showing the currents flowing through the oscillators in this embodiment and the conventional example, when the oscillation frequency is 32 kHz. The resistance of the resistor 11 mounted in the oscillator in this embodiment is 400 kΩ.

75. If the power supply voltage is 2.6 V, the current flowing through the oscillator in this embodiment is 1.4 μA, and the current flowing through the oscillator in the conventional oscillator is 2.1 μA. Also, if the applied voltage is 3.7 V, the current flowing through the oscillator in this embodiment is 2.7 μA, and the current flowing through the oscillator in the conventional example is 4.1 μA. The oscillator in this embodiment has the effect of the current reduction of about 34%, as compared with the oscillator in the conventional example.

76. Second Embodiment

77. With reference to FIG. 9, an oscillator of a second embodiment in the present invention is provided with a feedback circuit 50 and an amplifying circuit 80. In the oscillator of the second embodiment, the configuration of the amplifying circuit 80 is different from the amplifying circuit 60 in the first embodiment.

78. The amplifying circuit 80 is provided with an inverter 6, a feedback resistor 7 and a current adjuster 71. The inverter 6 and the feedback resistor 7 are connected parallel to each other between a node 5a and a node 5. An input terminal of the inverter 6 is connected to the node 5a. An output terminal of the inverter 6 is connected to the node 5. The node 5 is connected to a terminal 8b. Moreover, the node 5 is connected to an output terminal 9. The current adjuster 71 is mounted between a terminal 8a and the node 5a. The current adjuster 71 contains a resistor 21 and a switch 22. The resistor 21 and the switch 22 are connected parallel to each other between the terminal 8a and the node 5a. The configurations of the resistor 21 and the switch 22 are respectively similar to those of the resistor 11 and the switch 12 described in the first embodiment.

79. In the oscillator of the second embodiment, the terminal 5a and the terminal 8a are short-circuited at a time of an oscillation start so that an amplitude of the oscillation is made greater at a high speed. Thus, the oscillator becomes stable in a short time. Also, after the oscillation is stable, the terminal 5a and the terminal 8a are electrically connected through the resistor 21 to each other. Hence, a charging and discharging current of a capacitor 3a is reduced to thereby reduce a power consumption of the oscillator.

80. Third Embodiment

81. A third embodiment of an oscillator in the present invention will be described below. With reference to FIG. 10, the oscillator of the third embodiment is provided with a feedback circuit 50 and an amplifying circuit 90.

82. The configuration and the function of the feedback circuit 50 are identical to those of the first and second embodiments.

83. The amplifying circuit 90 is provided with an inverter 6, a feedback resistor 7 and a plurality of current adjusters 70, 71, 72 and 73. The current adjuster 71 is mounted between a terminal 5a and a terminal 8a. The terminal 5a is connected to an input of the inverter 6. An output of the inverter 6 is connected to the current adjuster 73. The current adjuster 73 is further connected to a terminal 5.

84. The terminal 5a is further connected to one terminal of the feedback resistor 7. The other terminal of the feedback resistor 7 is connected to the current adjuster 72. The current adjuster 72 is connected to the terminal 5. The terminal 5 is connected to an output terminal 9. The current adjuster 70 is mounted between the terminal 5 and the terminal 8b.

85. The current adjuster 70 has a resistor 11 and a switch 12. The resistor 11 and the switch 12 are connected parallel to each other. The current adjuster 71 has a resistor 21 and a switch 22. The resistor 21 and the switch 22 are connected parallel to each other. The current adjuster 72 has a resistor 31 and a switch 32. The resistor 31 and the switch 32 are connected parallel to each other. And, the current adjuster 73 has a resistor 41 and a switch 42. The resistor 41 and the switch 42 are connected parallel to each other. The configurations and the functions of the resistors 11, 21, 31 and 41 and the switches 12, 22, 32 and 42 are similar to the configurations and the functions of the resistor 11 and the switch 12 described in the first embodiment.

86. In the oscillator of the third embodiment, the switches 12, 22, 32, and 42 are turned on at a time of an oscillation start. Terminals of each of the resistors 11, 21, 31 and 41 are short-circuited. Then, an amplitude of an output signal Vout increases at a high speed. In the oscillator of the third embodiment, the oscillation becomes stable in a short time.

87. After the oscillation is stabilized, the switches 12, 22, 32, and 42 are turned off. The terminals 5 and 8b are electrically connected through the resistor 11. Also, the terminals 5 and 5a are connected through the resistor 7 and the resistor 31. Furthermore, the output terminal of the inverter 6 and the terminal 5 are electrically connected through the resistor 41. Furthermore, the terminals 5a and 8a are electrically connected through the resistor 21. Accordingly, charging and discharging currents of capacitors 3a, 3b are reduced to thereby suppress the power consumption of the oscillator in the third embodiment.

88. As for the oscillator of the third embodiment, it is required that at least one of the current adjusters 70 to 73 is included in the oscillator. At least one inclusion of the current adjusters 70 to 73 enables the reduction in the current flowing through the oscillator.

89. Although the invention has been described in its preferred form with a certain degree of particularity, it is understood that the present disclosure of the preferred form has been changed in the details of construction and the combination and arrangement of parts may be resorted to without departing from the spirit and the scope of the invention as hereinafter claimed.

What is claimed is:

1. An oscillator comprising:
a feedback circuit having first and second terminals, wherein said feedback circuit shifts a phase of a first signal inputted to said first terminal by substantially 180° to output a second signal from said second terminal; and
an amplifying circuit including:
an inverter having an output terminal and an input terminal, wherein said output terminal of said inverter is electrically connected to said first terminal and said input terminal of said inverter is electrically connected to said second terminal, and
a variable resistor element having first and second variable resistor terminals, wherein a resistance between said first and second variable resistor terminals is variable, and said first variable resistor terminal is electrically connected to said first terminal and said second variable resistor terminal is electrically connected to said second terminal.

2. An oscillator according to claim 1, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

3. An oscillator according to claim 1, wherein and said first variable resistor terminal is connected to said first terminal and said second variable resistor terminal is connected to said output terminal.

4. An oscillator according to claim 3, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

5. An oscillator according to claim 1, wherein said first variable resistor terminal is connected to said input terminal and said second variable resistor terminal is connected to said second terminal.

6. An oscillator according to claim 5, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

7. An oscillator according to claim 1, wherein said inverter and said variable resistor element are connected in parallel to each other.

8. An oscillator according to claim 7, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

9. An oscillator according to claim 1, wherein said amplifying circuit further includes a feedback resistor connected between third and fourth terminals, and
wherein said inverter and said variable resistor section are serially connected between said third and fourth terminals in parallel to said feedback resistor, and
wherein said third terminal is electrically connected to said first terminal, and said fourth terminal is electrically connected to said second terminal.

10. An oscillator according to claim 9, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

11. An oscillator according to claim 1, wherein said amplifying circuit further includes a feedback resistor, and said feedback resistor and said variable resistor section are serially connected between third and fourth terminals
wherein said inverter is connected between said third and fourth terminals in parallel to said feedback resistor and said variable resistor section, and
wherein said third terminal is electrically connected to said first terminal, and said fourth terminal is electrically connected to said second terminal.

12. An oscillator according to claim 11, wherein said variable resistor element comprises:
a resistor connected between said first and second variable resistor terminals; and
a switching element connected to said resistor in parallel to each other, and
wherein said first and second variable resistor terminals are substantially short-circuited by said switching element when said switching element is turned on.

13. An oscillator according to claim 1, wherein said feedback circuit includes:
a quarts oscillating element connected between said first and second terminals;
a first grounded terminal;
a first capacitor connected between said first terminal and said first grounded terminal;
a second grounded terminal;
a second capacitor connected between said second terminal and said second grounded terminal.

14. An oscillator according to claim 13, wherein a natural frequency of said quarts oscillating element is selected such that a charging and discharging current for charging and discharging said first and second capacitors is larger than a penetrating current flowing through said inverter when said inverter inverts an output voltage outputted from said output terminal.

15. A method of operating an oscillator including:
a feedback circuit having first and second terminals, wherein said feedback circuit shifts a phase of a first signal inputted to said first terminal by substantially 180° to output a second signal from said second terminal; and
an inverter having an output terminal and an input terminal, wherein said output terminal of said inverter is electrically connected to said first terminal and said input terminal of said inverter is electrically connected to said second terminal, and
a variable resistor element having first and second variable resistor terminals, wherein a resistance between said first and second variable resistor terminals is variable, and said first variable resistor terminal is electrically connected to said first terminal and said second variable resistor terminal is electrically connected to said second terminal, comprising:
supplying a power supply voltage to said inverter;
setting said resistance to a first resistance at a timing when said supplying is started; and
setting said resistance to a second resistance, a predetermined period after said timing, wherein said second resistance is larger than said first resistance.

16. A method according to claim 15, wherein said predetermined period is determined such that setting said resistance to said second resistance is executed after an amplitude of an oscillation occurring in said oscillator is saturated.

17. A method of operating an oscillator including:
a feedback circuit having first and second terminals, wherein said feedback circuit shifts a phase of a first signal inputted to said first terminal by substantially 180° to output a second signal from said second terminal,
an inverter having an output terminal, and an input terminal, wherein said output terminal of said inverter is electrically connected to said first terminal and said input terminal of said inverter is electrically connected to said second terminal,
a resistor connected between first and second variable resistor terminals, wherein said first variable resistor terminal is electrically connected to said first terminal and said second variable resistor terminal is electrically connected to said second terminal, and
a switching element connected to said resistor in parallel to each other, comprising:
supplying a power supply voltage to said inverter;
turning on said switching to short said first and second variable resistor terminals at a timing when said supplying is started;
turning off said switching element a predetermined period after said timing.

18. A method according to claim 17, wherein said predetermined period is determined such that setting said resistance to said second resistance is executed after an amplitude of an oscillation occurring in said oscillator is saturated.
